(19) United States
(12) Patent Application Publication
(10) Pub. No.: US 2025/0098151 A1
(43) Pub. Date: Mar. 20, 2025

(54) SEMICONDUCTOR DEVICE INCLUDING AIR GAP PROTECTION STRUCTURE WITH UNEVEN THICKNESS AND MANUFACTURING METHOD THEREOF

(71) Applicant: NANYA TECHNOLOGY CORPORATION, NEW TAIPEI CITY (TW)

(72) Inventor: WEI-CHUAN FANG, NEW TAIPEI CITY (TW)

(21) Appl. No.: 18/370,490

(22) Filed: Sep. 20, 2023

(51) Int. Cl. H10B 12/00

(52) U.S. Cl. CPC H10B 12/482; H10B 12/02; H10B 12/315

(57) ABSTRACT

A semiconductor device and method for manufacturing the same are provided. The semiconductor device includes a substrate, a bit line, an isolation spacer, a landing pad, and air gap protection structure. The bit line is disposed on the substrate. The isolation spacer is disposed on a side of the bit line. The isolation spacer includes an air gap. The landing pad is disposed over the bit line. The air gap protection structure covers the landing pad and the air gap. The air gap protection structure has an upper portion above a top surface of the landing pad and a lower portion below the upper portion. A ratio between a thickness of the lower portion and a thickness of the upper portion is greater than 0.6 and less than 0.8.

### TECHNICAL FIELD

The present disclosure relates to a semiconductor device and method for manufacturing the same, and more particularly, to a semiconductor device including an air gap protection structure with an uneven thickness and method for manufacturing the same.

### DISCUSSION OF THE BACKGROUND

With integrated circuits (ICs) achieving regular increases in performance and miniaturization, advances in materials and design produce successive generations with smaller and more complex circuits.

As the semiconductor industry develops, reducing overlay errors in lithography operations is becoming much more important. For example, when defining a pattern of a conductive wire to connect a landing pad, a relatively great overlay error may result in the conductive wire being misaligned with the landing pad, which may cause the material of the conductive wire to fill the air gap of an isolation spacer and negatively affect the electrical parameter of the a semiconductor device. Therefore, a new semiconductor device and method of improving such problems is required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a bit line, an isolation spacer, a landing pad, and air gap protection structure. The bit line is disposed on the substrate. The isolation spacer is disposed on a side of the bit line. The isolation spacer includes an air gap. The landing pad is disposed over the bit line. The air gap protection structure covers the landing pad and the air gap. The air gap protection structure has an upper portion above a top surface of the landing pad and a lower portion below the upper portion. A ratio between a thickness of the lower portion and a thickness of the upper portion is greater than 0.6 and less than 0.8.

Another aspect of the present disclosure provides a method of manufacturing a semiconductor device. The method includes: providing a substrate; forming a bit line on the substrate; forming an isolation spacer on a side of the bit line, wherein the isolation spacer comprises an air gap; forming a landing pad over the bit line; and forming an air gap protection structure to cover the landing pad and the air gap, wherein the air gap protection structure has an upper portion above a top surface of the landing pad and a lower portion below the upper portion, and a ratio between a thickness of the lower portion and a thickness of the upper portion is greater than 0.6.

Another aspect of the present disclosure provides a method of manufacturing a semiconductor device. The method includes: providing a substrate; forming a bit line on the substrate; forming an isolation spacer on a side of the bit line, wherein the isolation spacer comprises an air gap; forming a landing pad over the bit line; and performing a deposition process to form an air gap protection structure to cover the landing pad and the air gap, wherein a temperature during the deposition process ranges between about 530° C. and about 570° C.

The embodiments of the present disclosure illustrate a semiconductor device including an air gap protection structure with an uneven thickness. The air gap protection structure has a lower portion and an upper portion. The ratio between a thickness of the lower portion and a thickness of the upper portion is greater than 0.6 and less than 0.8 to protect the air gap from influence in subsequent processes. For example, the air gap of the present disclosure may be free of metal atoms or other contaminations by the protection of the air gap protection structure. As a result, the performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a cross-sectional view of a semiconductor device, in accordance with some embodiments of the present disclosure.

FIG. 1B is a partial enlarged view of a region R of the semiconductor device as shown in FIG. 1A, in accordance with some embodiments of the present disclosure.

FIG. 2A illustrates one or more stages of an exemplary method for manufacturing a semiconductor device according to some embodiments of the present disclosure.

FIG. 2B illustrates one or more stages of an exemplary method for manufacturing a semiconductor device according to some embodiments of the present disclosure.

FIG. 2C illustrates one or more stages of an exemplary method for manufacturing a semiconductor device according to some embodiments of the present disclosure.

FIG. 2D illustrates one or more stages of an exemplary method for manufacturing a semiconductor device according to some embodiments of the present disclosure.

FIG. 2E illustrates one or more stages of an exemplary method for manufacturing a semiconductor device according to some embodiments of the present disclosure.

FIG. 2F illustrates one or more stages of an exemplary method for manufacturing a semiconductor device according to some embodiments of the present disclosure.

FIG. 2G illustrates one or more stages of an exemplary method for manufacturing a semiconductor device according to some embodiments of the present disclosure.

FIG. 2H illustrates one or more stages of an exemplary method for manufacturing a semiconductor device according to some embodiments of the present disclosure.

FIG. 2I illustrates one or more stages of an exemplary method for manufacturing a semiconductor device according to some embodiments of the present disclosure.

FIG. 2J illustrates one or more stages of an exemplary method for manufacturing a semiconductor device according to some embodiments of the present disclosure.

FIG. 2K illustrates one or more stages of an exemplary method for manufacturing a semiconductor device according to some embodiments of the present disclosure.

FIG. 2L illustrates one or more stages of an exemplary method for manufacturing a semiconductor device according to some embodiments of the present disclosure.

FIG. 3A and FIG. 3B are flowcharts illustrating a method of manufacturing a semiconductor device, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

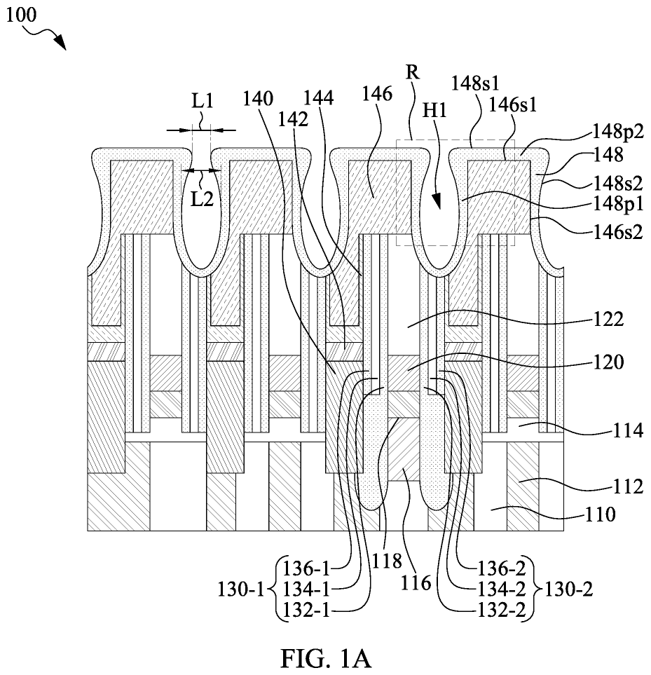

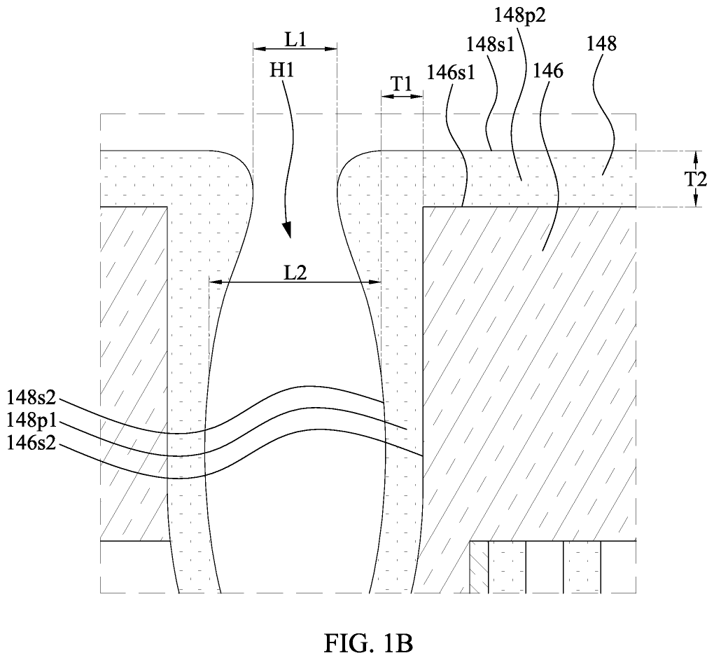

FIG. 1A is a cross-sectional view of a semiconductor device 100, in accordance with some embodiments of the present disclosure. In some embodiments, the semiconductor device 100 may include a cell region in which a memory device is formed. The memory device may include, for example, a dynamic random access memory (DRAM) device, a one-time programming (OTP) memory device, a static random access memory (SRAM) device, or other suitable memory devices. In some embodiments, a DRAM may include, for example, a transistor, a capacitor, and other components. During a read operation, a word line may be asserted, turning on the transistor. The enabled transistor allows the voltage across the capacitor to be read by a sense amplifier through a bit line. During a write operation, the data to be written may be provided on the bit line when the word line is asserted.

In some embodiments, the semiconductor device 100 may include a peripheral region (not shown) utilized to form a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices) or other devices.

The semiconductor device 100 may include a substrate 110. The substrate 110 may be a semiconductor substrate, such as a bulk semiconductor, a semiconductor-on-insulator (SOI) substrate, or the like. The substrate 110 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GalnAs, GaInP, and GalnAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 110 may have a multilayered structure, or the substrate 110 may include a multilayered compound semiconductor structure.

In some embodiments, the substrate 110 may include a plurality of active areas. The active area may function as, for example, a channel for electrical connection.

In some embodiments, the semiconductor device 100 may include isolation structures 112. In some embodiments, the plurality of active areas may be separated by the isolation structures 112. In some embodiments, the isolation spacer 112 may be embedded in the substrate 110. In some embodiments, the isolation spacer 112 may include, for example, silicon oxide (SiO₂), silicon nitride (Si₃N₄), silicon oxynitride (N₂OSi₂), silicon nitride oxide (N₂OSi₂), or other suitable materials.

In some embodiments, the semiconductor device 100 may include a dielectric layer 114. The dielectric layer 114 may be disposed on the substrate 110. In some embodiments, the dielectric layer 114 may cover a portion of the isolation spacer 112. In some embodiments, the dielectric layer 114 may include, for example, silicon oxide (SiO₂), silicon nitride (Si₃N₄), silicon oxynitride (N₂OSi₂), silicon nitride oxide (N₂OSi₂), a high-k material or combinations thereof. Examples of the high-k material include a dielectric material having a dielectric constant exceeding that of silicon dioxide (SiO₂), or a dielectric material having a dielectric constant higher than about 3.9. In some embodiments, the dielectric layer 114 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof.

In some embodiments, the semiconductor device 100 may include a bit line contact 116. In some embodiments, the bit line contact 116 may be disposed on the active area of the substrate 110. The bit line contact 116 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, combinations thereof or any metallic material with suitable resistance and gap-fill capability.

In some embodiments, the semiconductor device 100 may include bit line stacks 118. In some embodiments, the bit line stack 118 may include a multilayered structure. In some embodiments, a portion of the bit line stacks 118 may be disposed on the bit line contact 116. In some embodiments, a portion of the bit line stacks 118 may be in contact with the bit line contact 116. In some embodiments, a portion of the bit line stacks 118 may be electrically connected to the bit line contact 116. In some embodiments, a portion of the bit line stacks 118 may be disposed on the dielectric layer 114. In some embodiments, a portion of the bit line stacks 118 may be in contact with the dielectric layer 114. The bit line stack 118 may include titanium (Ti), tantalum (Ta), titanium nitride (TiN), tantalum nitride (TaN), manganese nitride (MnN) or a combination thereof.

In some embodiments, the semiconductor device 100 may include bit lines 120. In some embodiments, each of the bit lines 120 may be disposed on the bit line stack 118. In some embodiments, a portion of the bit lines 120 may be disposed on the bit line contact 116. In some embodiments, a portion of the bit lines 120 may be electrically connected to the bit line contact 116. In some embodiments, a portion of the bit lines 120 may be disposed on the dielectric layer 114. The bit line 120 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or combinations thereof.

In some embodiments, the semiconductor device 100 may include dielectric layers 122. In some embodiments, each of the dielectric layers 122 may be disposed on the bit line 120. In some embodiments, the dielectric layer 122 may include, for example, silicon oxide, silicon nitride, silicon oxynitride, silicon nitride oxide, a high-k material or combinations thereof.

In some embodiments, the semiconductor device 100 may include isolation spacers 130-1 and 130-2. The isolation spacer 130-1 may be disposed on a sidewall 120s1 of the bit line 120. The isolation spacer 130-2 may be disposed on a sidewall 120s2 of the bit line 120. It should be noted that although FIG. 1A illustrates the isolation spacers 130-1 and 130-2 separated in a cross-section, the isolation spacers 130-1 and 130-2 may be a part of an integral (or monolithic) structure, with said integral structure having a circular profile, an elliptical profile, or the like from a top view.

In some embodiments, the isolation spacer 130-1 may have a dielectric layer 132-1, an air gap 134-1, and a dielectric layer 136-1. In some embodiments, the isolation spacer 130-2 may have a dielectric layer 132-2, an air gap 134-2, and a dielectric layer 136-2. In some embodiments, the dielectric layers 132-1 and 132-2 may be formed on the sidewalls of the bit line contact 116, the bit line stack 118, the bit line 120, and the dielectric layer 122. For example, the dielectric layer 132-1 may be formed on the sidewall 120s1 of the bit line 120, and the dielectric layer 132-2 may be formed on the sidewall 120s2 of the bit line 120. In some embodiments, the dielectric layer 132-1 may be in contact with the sidewall 120s1 of the bit line 120. In some embodiments, the dielectric layer 132-2 may be in contact with the sidewall 120s2 of the bit line 120. In some embodiments, a portion of the dielectric layer 132-1 may be embedded in the substrate 110. In some embodiments, a portion of the dielectric layer 132-2 may be embedded in the substrate 110.

In some embodiments, the air gap 134-1 may be spaced apart from the bit line 120 by the dielectric layer 132-1. In some embodiments, the air gap 134-2 may be spaced apart from the bit line 120 by the dielectric layer 132-2. In some embodiments, the air gap 134-1 may be disposed between the dielectric layers 132-1 and 136-1. In some embodiments, the air gap 134-2 may be disposed between the dielectric layers 132-2 and 136-2. In some embodiments, the length of the air gap 134-2 may be less than that of the air gap 134-1. Although FIG. 1 illustrates that the air gap 134-1 is spaced apart from or distinct from the air gap 134-2, the air gap 134-1 may be connected to the air gap 134-2 in other embodiments.

In some embodiments, the dielectric layer 136-1 may be disposed on the dielectric layer 132-1. In some embodiments, the dielectric layer 136-2 may be disposed on the dielectric layer 132-2. In some embodiments, each of the dielectric layers 132-1, 132-2, 136-1 and/or 136-2 may include, for example, silicon oxide, silicon nitride, silicon oxynitride, silicon nitride oxide, a high-k material or combinations thereof. Although FIG. 1A illustrates that the dielectric layer 132-1 is spaced apart from the dielectric layer 136-1, the dielectric layer 132-1 may be connected to the dielectric layer 136-1 in other embodiments.

In some embodiments, the semiconductor device 100 may include a capacitor contact 140. In some embodiments, the capacitor contact 140 may be formed between two bit lines 120. In some embodiments, the capacitor contact 140 may be formed between the isolation spacers 130-1 and 130-2. In some embodiments, the capacitor contact 140 may be formed between the dielectric layers 136-1 and 136-2. In some embodiments, the capacitor contact 140 may be formed between a sidewall 130s1 of the isolation spacer 130-1 and a sidewall 130s2 of the isolation spacer 130-2. The capacitor contact 140 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, combinations thereof or any metallic material.

In some embodiments, the semiconductor device 100 may include a conductive stack structure 142. The conductive stack structure 142 may include a multilayered structure. In some embodiments, the conductive stack structure 142 may be formed on a top surface of the capacitor contact 140. In some embodiments, the conductive stack structure 142 may include metal silicide, such as, cobalt silicide (CoSi) or other suitable materials.

In some embodiments, the semiconductor device 100 may include a liner 144. In some embodiments, the liner 144 may be formed on a top surface of the capacitor contact 140. In some embodiments, the liner 144 may be formed on the sidewall 130s1 of the isolation spacer 130-1. In some embodiments, the liner 144 may be formed on a sidewall of the dielectric layer 136-1. In some embodiments, the liner 144 may be formed on the sidewall 130s2 of the isolation spacer 130-2. In some embodiments, the liner 144 may be formed on a sidewall of the dielectric layer 136-2. In some embodiments, the liner 144 may include metal nitride, such as titanium nitride (TiN) or other suitable materials.

In some embodiments, the semiconductor device 100 may include landing pads 146. The landing pad 146 may be configured to electrically connect a capacitor structure (not shown). In some embodiments, the landing pad 146 may be formed on the liner 144. In some embodiments, the landing pad 146 may be formed between two bit lines 120. In some embodiments, the landing pad 146 may be formed between the isolation spacers 130-1 and 130-2. In some embodiments, the landing pad 146 may cover a top surface the isolation spacer 130-1. In some embodiments, the landing pad 146 may cover a top surface of the dielectric layer 132-1. In some embodiments, the landing pad 146 may cover a top surface of the dielectric layer 136-1. In some embodiments, the air gap 134-1 may be covered by the landing pad 146. In some embodiments, the air gap 134-2 may be free from vertically overlapping the landing pad 146. In some embodiments, the landing pad 146 may cover a top surface the isolation spacer 130-2. In some embodiments, a portion of the landing pad 146 may be surrounded by the liner 144. In some embodiments, the landing pad 146 may cover a top surface of the dielectric layer 122. In some embodiments, the landing pad 146 may include an upper portion over the dielectric layer 122 and a lower portion between adjacent dielectric layers 122. In some embodiments, the landing pad 146 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or combinations thereof. The landing pad 146 may have a surface 146s1 and a surface 146s2. The surface 146s1 (or a top surface) may face away from the substrate 110. The surface 146s2 (or a lateral surface) may be connected to the lateral surface of the dielectric layer 122.

In some embodiments, the landing pad 146, the dielectric layer 122, and the isolation spacer 130-2 may define a hole H1 (or an opening). The hole H1 may have an aspect ratio equal to 2 or more, such as 2, 2.3, 2.5, 2.8, 3, or more. The aspect ratio may be defined as a ratio between a width (or an aperture) of the hole H1 (e.g., a distance between adjacent landing pads) and a depth of the hole H1 (e.g., a distance between the surface 146s1 and the top of the isolation spacer 130-2).

In some embodiments, the semiconductor device 100 may include an air gap protection structure 148. In some embodiments, the air gap protection structure 148 may be located within the hole H1. In some embodiments, the air gap protection structure 148 may cover the landing pads 146. In some embodiments, the air gap protection structure 148 may cover the isolation spacer 130-2. In some embodiments, the air gap 134-2 may be covered by the air gap protection structure 148. In some embodiments, the air gap protection structure 148 may be spaced apart from the isolation spacer 130-1 by the landing pad 146. The air gap protection structure 148 may have a surface 148s1 and a surface 148s2. The surface 148s1 (or a top surface) may face away from the substrate 110. The surface 148s2 (or a lateral surface) may cover the surface 146s2. The air gap protection structure 148 may be configured to protect the air gap 134-2 to ensure a desired parasitic capacitance. In some embodiments, the air gap protection structure 148 may have an uneven thickness. In some embodiments, the air gap protection structure 148 may include silicon nitride and other impurities. In some embodiments, the air gap protection structure 148 may include atoms, molecules, or ions of silicon, carbon, nitrogen, and hydrogen. In some embodiments, the air gap protection structure 148 may include carbon with atomic ratio greater than 4.8%, such as 4.8%, 4.9%, 5%, or more. In some embodiments, the air gap protection structure 148 may include silicon with atomic ratio between about 48% and about 50%. In some embodiments, the air gap protection structure 148 may include nitrogen with atomic ratio between about 46% and about 49%. In some embodiments, the atomic ratio of silicon of the air gap protection structure 148 may be greater than that of nitrogen.

Referring to FIG. 1B, the air gap protection structure 148 may have a lower portion 148p1 with a thickness T1 between the surfaces 146s2 and 148s2 and an upper portion 148p2 with a thickness T2 between the surfaces 146s1 and 148s1. The lower portion 148p1 may be located within the hole H1. The upper portion 148p2 may be located over the lower portion 148p1 and over the surface 146s1. In some embodiments, the thickness T1 may be less than the thickness T2. In some embodiments, the ratio between the thickness T1 and the thickness T2 may range between about 0.6 to about 0.8. In some embodiments, the ratio between the thickness T1 and the thickness T2 may be greater than 0.6, such as 0.61, 0.62, 0.63, 0.64, 0.65, 0.66, 0.67, 0.68, 0.69, 0.7, 0.72, 0.74, 0.76, 0.78, or 0.8.

The hole H1 defined by the air gap protection structure 148 may have a width L1 (or aperture) at the top (e.g., surface 148s1) of the air gap protection structure 148 and a width L2 (or aperture) at the middle or bottom of the air gap protection structure 148. In some embodiments, the width L1 may be less than the width L2.

As mentioned, the hole defined by the landing pad and the isolation structure has a relatively great aspect ratio (e.g., an aspect ratio greater than 2) and a narrower aperture at the top so that a dielectric material fills the hole difficultly. As a result, the lower portion of the air gap protection structure may have an insufficient thickness to protect the air gap well, leading to a poor parasitic capacitance. When the ratio between the lower portion 148p1 and the upper portion 148p2 of the air gap protection structure 148 is greater than 0.6, preferably equal to 0.66 or more, the air gap 134-2 may have a less influence in subsequent processes. For example, in a comparative example, metal atoms or other contaminations may diffuse into the air gap 134-2 in subsequent processes because the air gap 134-2 is not protected well. In this embodiment, the air gap 134-2 may be free of metal atoms or other contaminations by the protection of the air gap protection structure 148 whose lower portion 148p1 has a relatively large thickness.

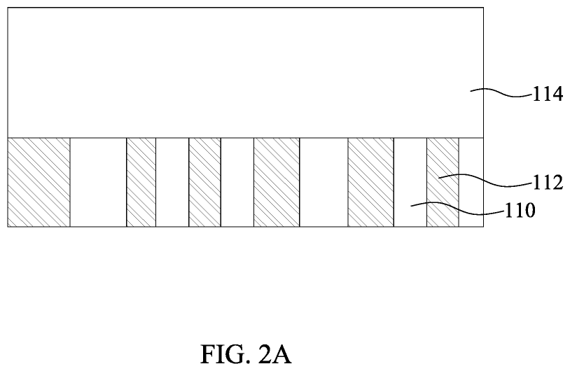

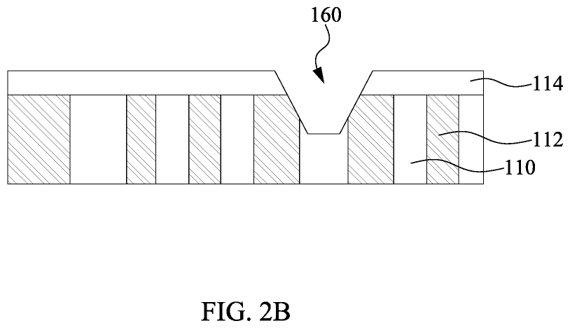

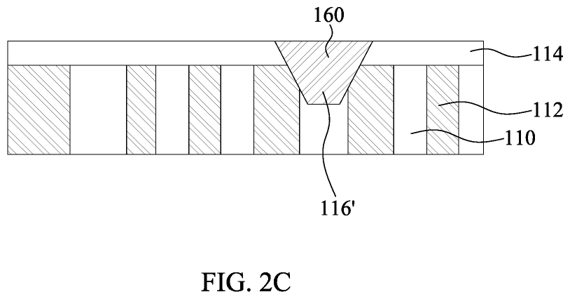

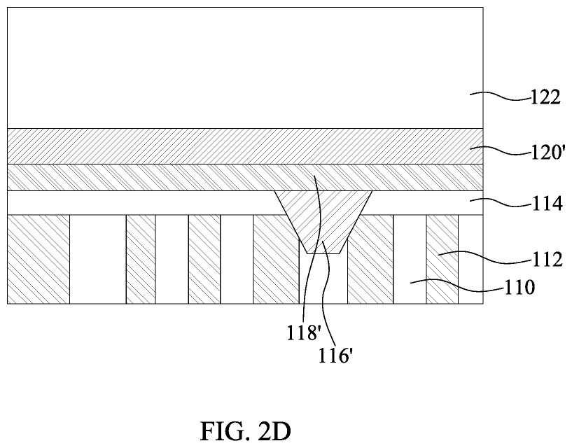

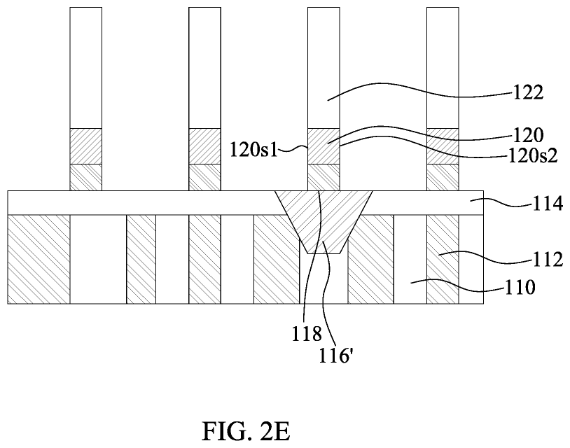

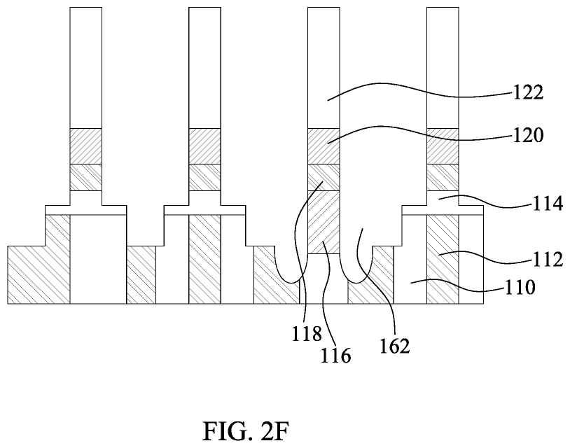

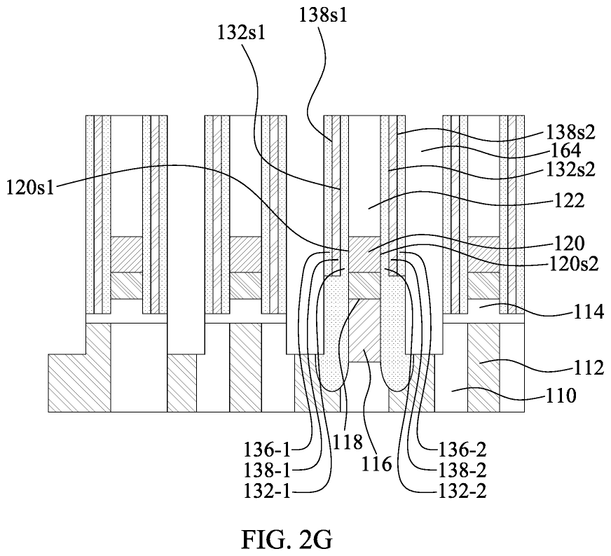

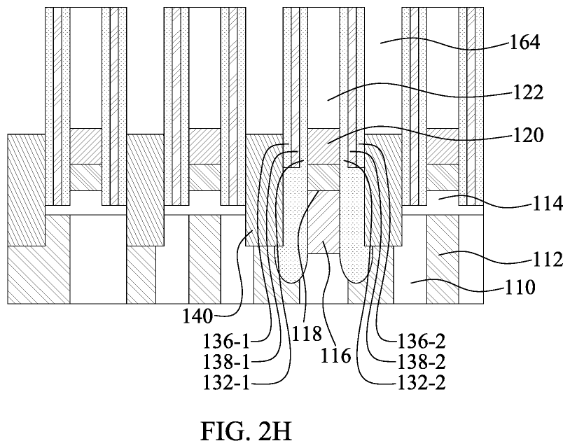

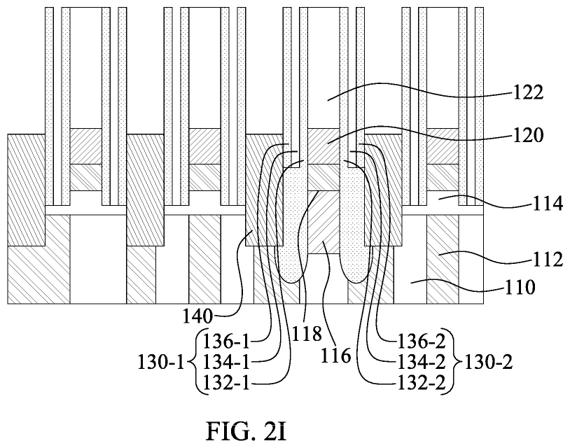

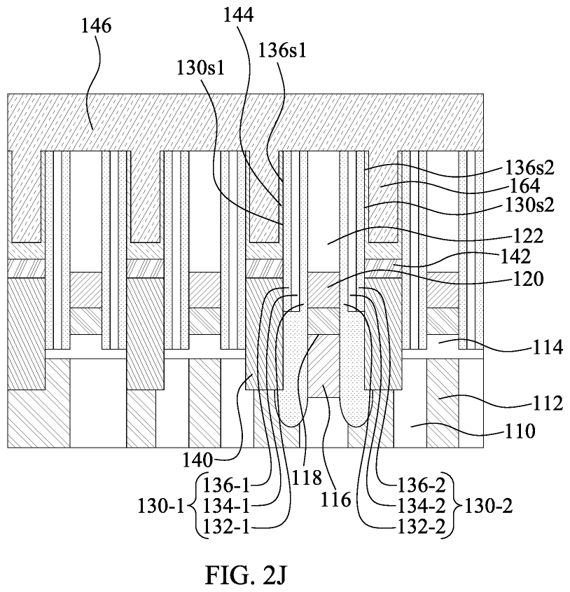

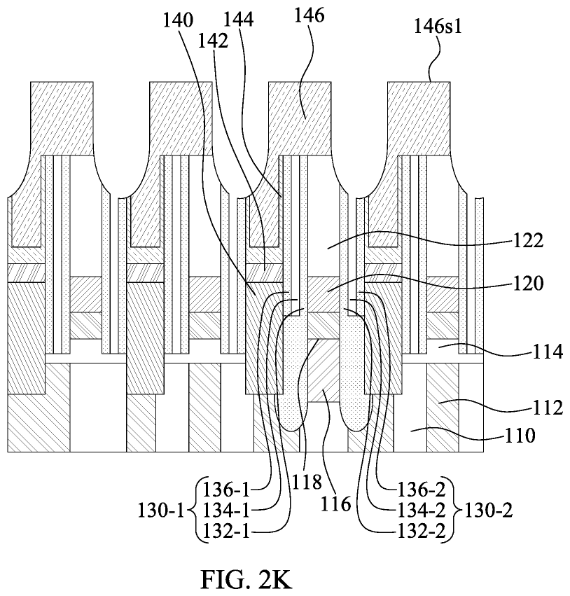

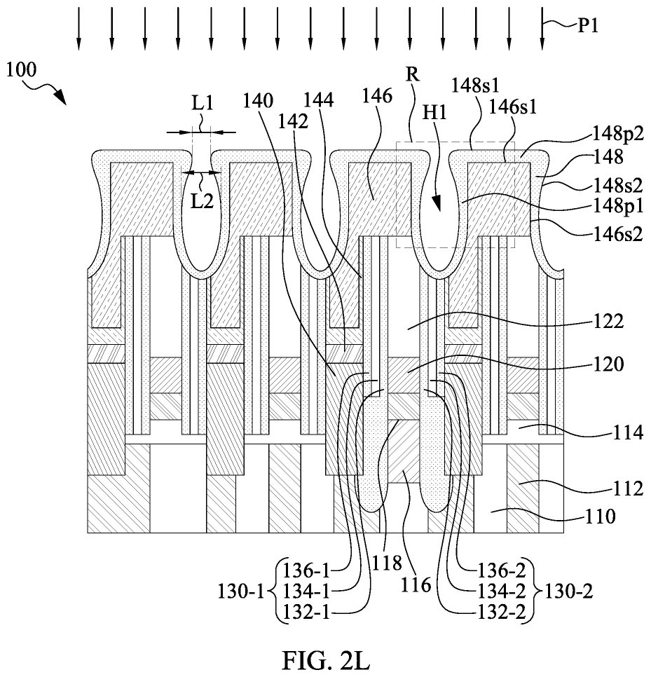

FIG. 2A to FIG. 2L illustrate stages of an exemplary method for manufacturing a semiconductor device according to some embodiments of the present disclosure.

Referring to FIG. 2A, a substrate 110 is provided. In some embodiments, the substrate 110 may include a plurality of active areas separated by isolation structures 112. A dielectric layer 114 may be formed on the substrate 110. In some embodiments, the substrate 110 may cover the active area and the isolation structures 112. In some embodiments, the dielectric layer 114 may be formed by chemical vapor deposition (CVD), atomic layer deposition (ALD), physical vapor deposition (PVD), low-pressure chemical vapor deposition (LPCVD), flowable chemical vapor deposition (FCVD), or other suitable process.

Referring to FIG. 2B, a trench 160 may be formed. In some embodiments, the trench 160 may be recessed from the substrate 110.

In some embodiments, the trench 160 may be recessed from the dielectric layer 114. In some embodiments, the trench 160 may be defined by the dielectric layer 114, the substrate 110, and the isolation structures 112. In some embodiments, an etching process may be performed to form the trench 160. The etching process may include dry etching, wet etching, or other suitable process.

Referring to FIG. 2C, a conductive layer 116′ may be formed. In some embodiments, the conductive layer 116′ may fill the trench 160. In some embodiments, the conductive layer 116′ may be surrounded by the dielectric layer 114. In some embodiments, the conductive layer 116′ may be surrounded by the substrate 110. In some embodiments, the conductive layer 116′ may be formed by CVD, ALD, PVD, FCVD, LPCVD, or other suitable process. Further, a chemical polishing process may be performed to planarize the top surfaces of the conductive material 116′ and the dielectric layer 114.

Referring to FIG. 2D, a barrier layer 118′, a metallization layer 120′, and a dielectric layer 122 may be formed. The barrier layer 118′ may be formed by CVD, ALD, PVD, FCVD, LPCVD, or other suitable process. The metallization layer 120′ may be formed on the barrier layer 118′. The metallization layer 120′ may be formed by CVD, ALD, PVD, FCVD, LPCVD, or other suitable process. The dielectric layer 122 may be formed on the metallization layer 120′. The dielectric layer 122 may be formed by CVD, ALD, PVD, FCVD, LPCVD, or other suitable process.

In some embodiments, the barrier layer 118′ may cover the substrate 110. In some embodiments, the barrier layer 118′ may cover the dielectric layer 114.

In some embodiments, the metallization layer 120′ may be configured to form bit lines 120. In some embodiments, the metallization layer 120′ may cover the barrier layer 118′.

In some embodiments, the dielectric layer 122 may cover the metallization layer 120′.

Referring to FIG. 2E, a portion of the metallization layer 120′ may be removed, thereby forming bit lines 120. In some embodiments, a portion of the barrier layer 118′ may be removed, thereby forming bit line stacks 118. In some embodiments, a portion of the dielectric layer 122 may be removed. An etching process may be performed to remove the portions of the metallization layer 120′, the barrier layer 118′, and the dielectric layer 122. The etching process may include dry etching, wet etching, or other suitable process.

In some embodiments, a sidewall 120s1 of the bit line 120 may be exposed. A sidewall 120s2 of the bit line 120 may be exposed. It should be noted that the each of the dielectric layer 122, the bit line 120, and the bit line stack 118 may have a circular profile, an elliptical profile, or the like from a top view, and the sidewall of the each of dielectric layer 122, the bit line 120, and the bit line stack 118 may refer to a lateral edge in a cross-section.

In some embodiments, a portion of the conductive layer 116′ may be exposed by the bit line stack 118. In some embodiments, the portion of the conductive layer 116′ may be exposed by the bit line 120. In some embodiments, the portion of the conductive layer 116′ may be exposed by the dielectric layer 122.

In some embodiments, a portion of the bit lines 120 may be disposed over the conductive layer 116′. In some embodiments, a portion of the bit line stacks 118 may be disposed over the conductive layer 116′. In some embodiments, a portion of the bit lines 120 may be disposed over the isolation structures 112. In some embodiments, a portion of the bit line stacks 118 may be disposed over the isolation structures 112.

Referring to FIG. 2F, a portion of the conductive layer 116′ is removed, thereby forming a bit line contact 116 within the trench 162. In some embodiments, the portion of the conductive layer 116′ exposed by the bit line 120 may be removed. In some embodiments, the portion of the conductive layer 116′ exposed by the bit line stack 118 may be removed. In some embodiments, the portion of the conductive layer 116′ exposed by the dielectric layer 122 may be removed. The bit line 116 may be tapered along a direction from the bit line 120 toward the substrate 110.

Referring to FIG. 2G, dielectric layers 132-1, 132-2, 138-1, 138-2, 136-1, and 136-2 may be formed. In some embodiments, the dielectric layers 132-1 and 132-2 may be formed on the sidewalls of the bit line contact 116, the bit line stack 118, the bit line 120, and the dielectric layer 122. For example, the dielectric layer 132-1 may be formed on the sidewall 120s1 of the bit line 120, and the dielectric layer 132-2 may be formed on the sidewall 120s2 of the bit line 120. In some embodiments, the dielectric layer 132-1 may be in contact with the sidewall 120s1 of the bit line 120. In some embodiments, the dielectric layer 132-2 may be in contact with the sidewall 120s2 of the bit line 120. It should be noted that the dielectric layer 132-1 and the dielectric layer 132-2 may be a part of an integral (or monolithic) structure, and said integral structure may have a circular profile, an elliptical profile, or the like from a top view.

In some embodiments, the dielectric layer 138-1 may be disposed on a sidewall 132s1 of the dielectric layer 132-1. In some embodiments, the dielectric layer 138-2 may be disposed on a sidewall 132s2 of the dielectric layer 132-2. It should be noted that the dielectric layers 138-1 and 138-2 may be a part of an integral (or monolithic) structure, and the said integral structure may have a circular profile, an elliptical profile, or the like from a top view.

In some embodiments, the dielectric layer 136-1 may be disposed on a sidewall 138s1 of the dielectric layer 138-1. In some embodiments, the dielectric layer 136-2 may be disposed on a sidewall 138s2 of the dielectric layer 138-2. In some embodiments, the dielectric layer 136-1 may be spaced apart from the dielectric layer 132-1 by the dielectric layer 138-1. In some embodiments, the dielectric layer 136-2 may be spaced apart from the dielectric layer 132-2 by the dielectric layer 138-2. It should be noted that the dielectric layers 136-1 and 136-2 may be a part of an integral (or monolithic) structure, and the said integral structure may have a circular profile, an elliptical profile, or the like from a top view.

In some embodiments, the dielectric layer 138-1 may be a material different from the dielectric layers 132-1 and 136-1. In some embodiments, the dielectric layer 132-1 may be a material the same as that of the dielectric layer 136-1. In some embodiments, the dielectric layer 138-2 may be a material different from the dielectric layers 132-2 and 136-2. In some embodiments, the dielectric layer 132-2 may be a material the same as that of the dielectric layer 136-2. A trench 164 may be defined between the dielectric layers 136-1 and 136-2. The profiles of the dielectric layers 132-1, 132-2, 138-1, 138-2, 136-1, and 136-2 may be modified by suitable etching processes, and the present disclosure is not intended to be limiting.

Referring to FIG. 2H, a capacitor contact 140 may be formed. The capacitor contact 140 may be formed within the trench 164. The capacitor contact 140 may be formed by, for example, CVD, ALD, PVD, FCVD, LPCVD, or other suitable process. In some embodiments, the capacitor contact 140 may be formed between two bit lines 120. In some embodiments, the capacitor contact 140 may be formed between the dielectric layers 136-1 and 136-2.

Referring to FIG. 2I, the dielectric layer 138-1 may be removed, which thereby forms an air gap 134-1. The dielectric layer 138-2 may be removed, which thereby forms an air gap 134-2. As a result, isolation spacers 130-1 and 130-2 may be produced. In some embodiments, the air gap 134-1 may be spaced apart from the bit line 120 by the dielectric layer 132-1. In some embodiments, the air gap 134-2 may be spaced apart from the bit line 120 by the dielectric layer 132-2. The dielectric layer 138-1 and dielectric layer 138-2 may be removed by an etching process, such as dry etching, wet etching, or other suitable process.

Referring to FIG. 2J, a conductive stack structure 142, a liner 144, and a landing pad 146 may be formed. The conductive stack structure 142 may be formed within the trench 160. In some embodiments, the conductive stack structure 142 may be formed on a top surface of the capacitor contact 140. In some embodiments, the conductive stack structure 142 may be formed between the dielectric layers 136-1 and 136-2. Each of the conductive stack structure 142, the liner 144, and the landing pad 146 may be formed by CVD, ALD, PVD, FCVD, LPCVD, or other suitable process.

In some embodiments, the liner 144 may be formed on a top surface of the capacitor contact 140. In some embodiments, the liner 144 may be formed on a sidewall 130s1 of the isolation spacer 130-1. In some embodiments, the liner 144 may be formed on a sidewall 136s1 of the dielectric layer 136-1. In some embodiments, the liner 144 may be formed on a sidewall 130s2 of the isolation spacer 130-2. In some embodiments, the liner 144 may be formed on a sidewall 136s2 of the dielectric layer 136-2.

In some embodiments, the landing pad 146 may be formed on the liner 144. In some embodiments, the landing pad 146 may be formed between two bit lines 120. In some embodiments, the landing pad 146 may be formed between the isolation spacers 130-1 and 130-2. In some embodiments, the landing pad 146 may cover a top surface of the isolation spacer 130-1. In some embodiments, the landing pad 146 may cover a top surface of the dielectric layer 132-1. In some embodiments, the landing pad 146 may cover a top surface of the dielectric layer 136-1. In some embodiments, the air gap 134-1 may be covered by the landing pad 146. In some embodiments, the landing pad 146 may cover a top surface the isolation spacer 130-2. In some embodiments, the landing pad 146 may cover a top surface of the dielectric layer 132-2. In some embodiments, the landing pad 146 may cover a top surface of the dielectric layer 136-2. In some embodiments, the air gap 134-2 may be covered by the landing pad 146. In some embodiments, the landing pad 146 may cover a top surface of the dielectric layer 122. In some embodiments, the landing pad 146 may be formed within the trench 164 defined by the isolation spacers 130-1 and 130-2.

Referring to FIG. 2K, a portion of the landing pad 146 may be removed or patterned. Holes H1 may be defined by the landing pads 146, the dielectric layer 122, and the isolation spacer 130-2. The landing pad 146 may be removed by an etching process. In some embodiments, the hole H1 may have an aspect ratio greater than 2.

Referring to FIG. 2L, a deposition process P1 may be performed to form an air gap protection structure 148 within the holes H1, which thereby produces a semiconductor device 100. The air gap protection structure 148 may be formed by ALD, CVD, PVD, or other suitable processes. The air gap protection structure 148 may have a lower portion 148p1 and an upper portion 148p2. In some embodiments, the ratio between the thickness of the lower portion 148p1 and the thickness of the upper portion 148p2 may be greater than 0.6, preferably equal to or greater than 0.66.

In some embodiments, the hole H1 may have a smaller width or aperture (e.g., L1) at the top (e.g., surface 148s1) of the air gap protection structure 148 and a greater width or aperture (e.g., L2) at the middle or bottom of the air gap protection structure 148.

In some embodiments, the air gap protection structure may include silicon nitride and other impurities, such as carbon and/or hydrogen. In some embodiments, the temperature of the deposition process P1 may range from about 530° C. to about 570° C., such as 530° C., 540° C., 550° C., 560° C., or 570° C.

In some embodiments, the pressure of the deposition process P1 may less than 3 torr, such as 3 torr, 2.5 torr, 2 torr, 1.5 torr, or 1 torr, or less.

In some embodiments, the deposition process P1 may include using gas, including reactive gas(s) and non-reactive gas(s), of silane (SiH₄), ammonia (NH₃), tetramethylsilane (TMS), nitrogen (N₂), or a combination thereof. In some embodiments, the deposition process P1 is free of helium (He). More specifically, during the step of depositing the air gap protection structure 148, He is not used. However, the stages before or after deposition of the air gap protection structure 148, such as heating, cooling, purge, or other steps, He may be used.

In some embodiments, the flow rate of the SiH₄ during the deposition process P1 may be equal to or greater than 200 sccm, such as 200 sccm, 220 sccm, 240 sccm, 260 sccm, 280 sccm, 300 sccm, 320 sccm, or more.

In some embodiments, the flow rate of the NH₃ during the deposition process P1 may be equal to or greater than 600 sccm, such as 600 sccm, 1500 sccm, 2200 sccm, 2700 sccm, 3200 sccm, 4000 sccm, or more.

In some embodiments, the flow rate of the TMS during the deposition process P1 may be equal to or greater than 45 sccm, such as 45 sccm, 48 sccm, 50 sccm, 55 sccm, or more.

In some embodiments, the flow rate of the N₂ during the deposition process P1 may be equal to or less than 10000 sccm, such as 10000 sccm, 7000 sccm, 4000 sccm, 1000 sccm, or less.

In some embodiments, the deposition rate of the air gap protection structure 148 may be equal to or less than 15 Å, such as 12 Å, 10 Å, 8 Å, 5 Å, or less.

By the process conditions mentioned above, the ratio between the thickness T1 and the thickness T2 of the air gap protection structure 148 may be greater than 0.6, which thereby protects the air gap 134-2 in subsequent processes.

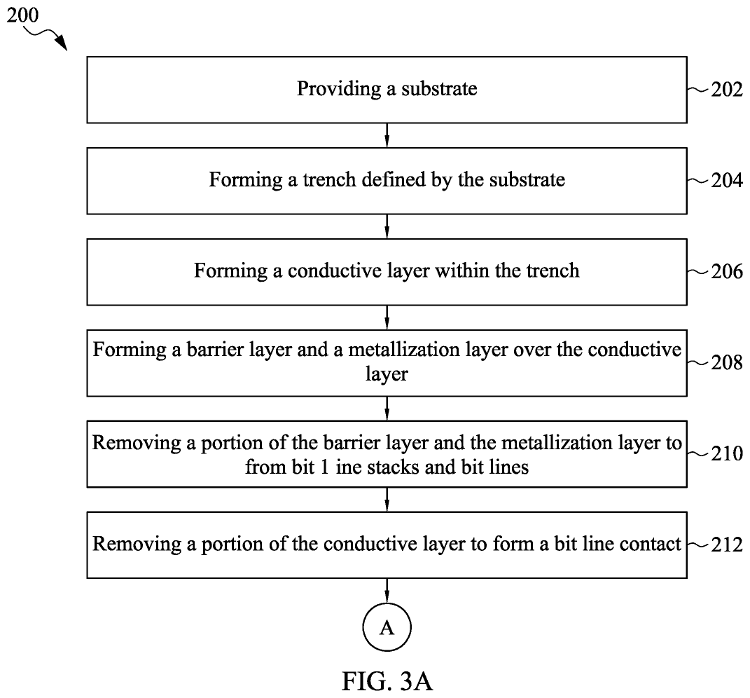

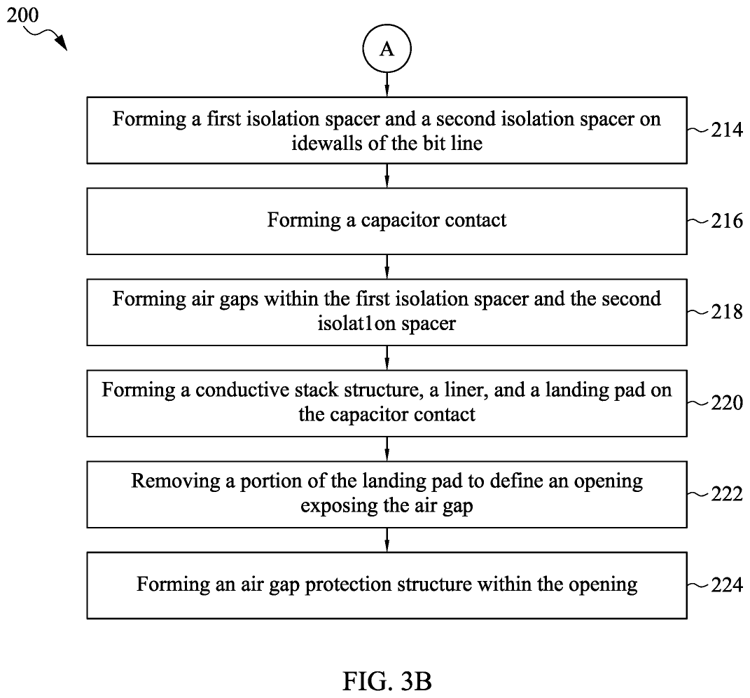

FIGS. 3A and 3B are flowcharts illustrating a method 200 of manufacturing a semiconductor device, in accordance with some embodiments of the present disclosure.

Referring to FIG. 3A, the method 200 begins with operation 202 in which a substrate is provided. In some embodiments, the substrate may include a plurality of active areas separated by isolation structures. A first dielectric layer may be formed on the substrate. In some embodiments, the substrate may cover the active area and the isolation structures. In some embodiments, a plurality of word lines may be formed within the substrate.

The method 200 continues with operation 204 in which a trench may be formed. In some embodiments, the trench may be formed by the etching process. In some embodiments, the trench may be recessed from the substrate. In some embodiments, the trench may be recessed from the first dielectric layer. In some embodiments, the trench may be defined by the first dielectric layer, the substrate, and the isolation structures.

The method 200 continues with operation 206 in which a conductive layer may be formed. In some embodiments, the conductive layer may fill the trench. In some embodiments, the conductive layer may be surrounded by the first dielectric layer.

The method 200 continues with operation 208 in which a barrier layer, a metallization layer, and a second dielectric layer may be formed. The barrier layer may cover the substrate. The metallization layer may be formed on the barrier layer. The second dielectric layer may be formed on the metallization layer.

The method 200 continues with operation 210 in which a portion of the metallization layer may be removed, thereby forming bit lines. In some embodiments, a portion of the barrier layer may be removed, thereby forming bit line stacks. In some embodiments, a portion of the second dielectric layer may be removed. An etching process may be performed to remove the portion of the metallization layer, the barrier layer, and the second dielectric layer.

In some embodiments, a sidewall of the bit line may be exposed. In some embodiments, a sidewall of the bit line stack may be exposed. In some embodiments, a sidewall of the second dielectric layer may be exposed.

In some embodiments, a portion of the conductive layer may be exposed by the bit line stack. In some embodiments, the portion of the conductive layer may be exposed by the bit line. In some embodiments, the portion of the conductive layer may be exposed by the second dielectric layer.

In some embodiments, a portion of the bit lines may be disposed over the conductive layer. In some embodiments, a portion of the bit line stacks may be disposed over the conductive layer. In some embodiments, a portion of the bit lines may be disposed over the isolation structures. In some embodiments, a portion of the bit line stacks may be disposed over the isolation structures.

The method 200 continues with operation 212 in which a portion of the conductive layer is removed, thereby forming a bit line contact within the trench. In some embodiments, the portion of the conductive layer exposed by the bit line may be removed. In some embodiments, the portion of the conductive layer exposed by the second dielectric layer may be removed. The bit line may be tapered from the bit line toward the substrate.

Referring to FIG. 3B, the method 200 continues with operation 214 in which a first isolation spacer and a second isolation spacer may be formed. The first isolation spacer may be formed on a first side of the bit line. The second isolation spacer may be formed on a second side of the bit line. Each of the first isolation spacer and the second isolation spacer may have a multilayered structure. For example, each of the first isolation spacer and the second isolation spacer may have a structure made of silicon nitride/silicon oxide/silicon nitride.

The method 200 continues with operation 216 in which a capacitor contact may be formed. In some embodiments, an etching process may be performed to remove a portion of the substrate and the first dielectric layer to form a trench, and the capacitor contact may be formed within the said trench. In some embodiments, the capacitor contact may be formed between two of the bit lines. In some embodiments, the capacitor contact may be formed between the first isolation spacer and the second isolation spacer.

The method 200 continues with operation 218 in which an air gap may be formed within each of the first isolation spacer and the second isolation spacer. For example, silicon oxide layer of the first isolation spacer and the second isolation spacer may be removed, thereby forming air gaps. In some embodiments, the air gap may be spaced apart from the bit line by silicon nitride layer.

The method 200 continues with operation 220 in which a conductive stack structure, a liner, and a landing pad may be formed. In some embodiments, the conductive stack structure may be formed on a top surface of the capacitor contact.

In some embodiments, the liner may be formed on a top surface of the capacitor contact. In some embodiments, the liner may be formed on a sidewall of the first isolation spacer. In some embodiments, the liner may be formed on a sidewall of the second isolation spacer.

In some embodiments, the landing pad may be formed on the liner. In some embodiments, the landing pad may be formed between two of the bit lines. In some embodiments, the landing pad may be formed between the first isolation spacer and the second isolation spacer. In some embodiments, the landing pad may cover a top surface the first isolation spacer. In some embodiments, the air gap of the first isolation spacer may be covered by the landing pad. In some embodiments, the landing pad may cover a top surface the second isolation spacer. In some embodiments, the air gap of the second isolation spacer may be covered by the landing pad.

The method 200 continues with operation 222 in which a portion of the landing pad may be removed. A hole may be defined by the landing pad, the dielectric structure, and the first isolation spacer. A portion of the air gap may be exposed. The aspect ratio of the hole may be greater than 2.

The method 200 continues with operation 224 in which an air gap protection structure may be formed. A deposition process may be performed to form the air gap protection structure.

In some embodiments, the air gap protection structure may include silicon nitride and other impurities, such as carbon and/or hydrogen. In some embodiments, the temperature of the deposition process may range from about 530° C. to about 570° C., such as 530° C., 540° C., 550° C., 560° C., or 570° C.

In some embodiments, the pressure of the deposition process may less than 3 torr, such as 3 torr, 2.5 torr, 2 torr, 1.5 torr, or 1 torr, or less.

In some embodiments, the deposition process may include using gas of SiH₄, NH₃, TMS, N₂, or a combination thereof. In some embodiments, the deposition process is free of He.

In some embodiments, the flow rate of SiH₄ during the deposition process may be equal to or greater than 200 sccm, such as 200 sccm, 220 sccm, 240 sccm, 260 sccm, 280 sccm, 300 sccm, 320 sccm, or more.

In some embodiments, the flow rate of NH₃ during the deposition process may be equal to or greater than 600 sccm, such as 600 sccm, 1500 sccm, 2200 sccm, 2700 sccm, 3200 sccm, 4000 sccm, or more.

In some embodiments, the flow rate of TMS during the deposition process may be equal to or greater than 45 sccm, such as 45 sccm, 48 sccm, 50 sccm, 55 sccm, or more.

In some embodiments, the flow rate of N₂ during the deposition process may be equal to or less than 10000 sccm, such as 10000 sccm, 7000 sccm, 4000 sccm, 1000 sccm, or less.

In some embodiments, the deposition rate of the air gap protection structure may be equal to or less than 15 Å/sec, such as 12 Å/sec, 10 Å/sec, 8 Å/sec, 5 Å/sec, or less.

By the process conditions mentioned above, the lower portion of the air gap protection structure may have a sufficient thickness, which facilitates in the protection the air gap during subsequent processes.

The method 200 is merely an example, and is not intended to limit the present disclosure beyond what is explicitly recited in the claims. Additional operations may be provided before, during, or after each operation of the method 200, and some operations described may be replaced, eliminated, or reordered for additional embodiments of the method. In some embodiments, the method 200 may include further operations not depicted in FIG. 3A or FIG. 3B. In some embodiments, the method 200 may include one or more operations depicted in FIG. 3A and FIG. 3B.

One aspect of the present disclosure provides a semiconductor device. The semiconductor device includes a substrate, a bit line, an isolation spacer, a landing pad, and air gap protection structure. The bit line is disposed on the substrate. The isolation spacer is disposed on a side of the bit line. The isolation spacer includes an air gap. The landing pad is disposed over the bit line. The air gap protection structure covers the landing pad and the air gap. The air gap protection structure has an upper portion above a top surface of the landing pad and a lower portion below the upper portion. A ratio between a thickness of the lower portion and a thickness of the upper portion is greater than 0.6.

Another aspect of the present disclosure provides a method of manufacturing a semiconductor device. The method includes: providing a substrate; forming a bit line on the substrate; forming an isolation spacer on a side of the bit line, wherein the isolation spacer comprises an air gap; forming a landing pad over the bit line; and forming an air gap protection structure to cover the landing pad and the air gap, wherein the air gap protection structure has an upper portion above a top surface of the landing pad and a lower portion below the upper portion, and a ratio between a thickness of the lower portion and a thickness of the upper portion is greater than 0.6.

Another aspect of the present disclosure provides a method of manufacturing a semiconductor device. The method includes: providing a substrate; forming a bit line on the substrate; forming an isolation spacer on a side of the bit line, wherein the isolation spacer comprises an air gap; forming a landing pad over the bit line; and performing a deposition process to form an air gap protection structure to cover the landing pad and the air gap, wherein a temperature during the deposition process ranges between about 530° C. and about 570° C.

The embodiments of the present disclosure illustrate a semiconductor device including an air gap protection structure with an uneven thickness. The air gap protection structure has a lower portion and an upper portion. The ratio between a thickness of the lower portion and a thickness of the upper portion is greater than 0.6 and less than 0.8 to protect the air gap from influence in subsequent processes. For example, the air gap of the present disclosure may be free of metal atoms or other contaminations by the protection of the air gap protection structure. As a result, the performance of the semiconductor device may be improved.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a bit line disposed on the substrate;
an isolation spacer disposed on a side of the bit line, wherein the isolation spacer comprises an air gap;
a landing pad disposed over the bit line; and
an air gap protection structure covering the landing pad and the air gap, wherein the air gap protection structure has an upper portion above a top surface of the landing pad and a lower portion below the upper portion, and a ratio between a thickness of the lower portion and a thickness of the upper portion is greater than 0.6 and less than 0.8.

2. The semiconductor device of claim 1, wherein the air gap protection structure comprises silicon nitride.

3. The semiconductor device of claim 2, wherein the air gap protection structure comprises carbon.

4. The semiconductor device of claim 3, wherein an atomic ratio of carbon is greater than 4.8%.

5. The semiconductor device of claim 2, wherein the air gap protection structure comprises hydrogen.

6. The semiconductor device of claim 1, wherein a hole is defined by the landing pad and located over the air gap, and the air gap protection structure is located within the hole.

7. The semiconductor device of claim 6, wherein the hole defined by the air gap protection structure has a smaller aperture near the upper portion of the air gap protection structure and a greater aperture near the lower portion of the air gap protection structure.

8. The semiconductor device of claim 6, wherein an aspect ratio of the hole is greater than 2.

9. The semiconductor device of claim 1, further comprising:
a capacitor contact spaced apart from the bit line by the isolation spacer.

10. The semiconductor device of claim 1, wherein the ratio between the thickness of the lower portion and the thickness of the upper portion of the air gap protection structure is equal to or greater than 0.66.

11. A method of manufacturing a semiconductor device, comprising:
providing a substrate;
forming a bit line on the substrate;
forming an isolation spacer on a side of the bit line, wherein the isolation spacer comprises an air gap;
forming a landing pad over the bit line; and
forming an air gap protection structure to cover the landing pad and the air gap, wherein the air gap protection structure has an upper portion above a top surface of the landing pad and a lower portion below the upper portion, and a ratio between a thickness of the lower portion and a thickness of the upper portion is greater than 0.6 and less than 0.8.

12. The method of claim 11, wherein the air gap protection structure comprises silicon nitride.

13. The method of claim 12, wherein the air gap protection structure comprises carbon.

14. The method of claim 12, wherein the air gap protection structure comprises hydrogen.

15. The method of claim 11, further comprising:
patterning the landing pad to define a hole over the air gap, wherein the lower portion of the air gap protection structure is formed within the hole.

16. The method of claim 15, wherein the hole defined by the air gap protection structure has a smaller aperture near the upper portion of the air gap protection structure and a greater aperture near the lower portion of the air gap protection structure.

17. The method of claim 15, wherein an aspect ratio of the hole is greater than 2.

18. The method of claim 11, wherein the ratio between the thickness of the lower portion and the thickness of the upper portion of the air gap protection structure is equal to or greater than 0.66.

19. The method of claim 11, wherein forming the air gap protection structure comprises performing a deposition process, and gases used in the deposition process comprise SiH₄, NH₃, tetramethylsilane, and N₂.

20. The method of claim 11, wherein He is not used during depositing the air gap protection structure.
